(19) United States
(12) Patent Application Publication
(10) Pub. No.: US 2005/0173809 A1
(43) Pub. Date: Aug. 11, 2005

(54) Wafer-level package and method for production thereof

(76) Inventors: Yukihiro Yamamoto, Chiba (JP); Keiji Iwata, Chiba (JP); Yukio Sasaki, Chiba (JP); Kohei Tatsumi, Chiba (JP); Vivek B. Dutta, Cupertino, CA (US); Tomofumi Jin, Chiba (JP); Koji Nakamura, Chiba (JP); Shinji Inaba, Chiba (JP)

Correspondence Address: MATHEWS, SHEPHERD, MCKAY, & BRUNEAU, P.A., 100 THANET CIRCLE, SUITE 306, PRINCETON, NJ, 08540, US

(21) Appl. No.: 11/038,299

(22) Filed: Jan. 19, 2005

(30) Foreign Application Priority Data
Jan. 22, 2004 (JP) 2004-014356

(51) Int. Cl. H01L 23/48; H01L 21/48

(52) U.S. Cl. 257/780; 438/108

(57) ABSTRACT

This invention is aimed at providing a wafer-level package which is capable of relaxing the stress in a chip-size package and exalting the reliability of the operation of mounting on a printed board and a method for the production thereof. This invention is directed toward a wafer-level package of a semiconductor substrate possessed of either or both of an electrode part and a wiring layer connected to an electrode part, which is provided on the semiconductor substrate with an insulating layer formed mainly of a fluorene skeleton-containing resin and on the electrode part with one step or a plurality of steps of posts, and on the posts with bumps formed of electroconductive balls and a method for the production thereof.

### BACKGROUND OF THE INVENTION

1. Field of the Invention

This invention relates to a wafer-level chip size package and a method for the production thereof and to a technology for enhancing the reliability thereof.

2. Description of Related Art

The technologies which the present inventors have studied concern the production of semiconductor devices and include the following technologies which pertain to the bump structures of wafer-level CSP (chip size package) and WPP (wafer process package). The wafer-level CSP and the WPP designate the wafer-level packaging technology for performing a processing treatment called tail-end step on a wafer level. The wafer-level packages are formed as LSI packages which have nearly similar outside dimensions as chips.

Heretofore, the structure generally called a BGA (ball grid array) and furnished on the surface thereof with a plurality of arrayed solder balls and the structure called a fine pitch BGA and adapted to have the balls of BGA arrayed with a smaller pitch and consequently allowed to assume outside dimensions approximating those of chips have been known. The wafer-level CSP is fundamentally the type of CSP that has a wiring and a pad of the form of an array fabricated by the wafer process into a chip before the chip is diced. By this technology, the wafer process and the package process are unified to decrease the cost of packaging greatly (refer, for example, to the August 1998 issue of “Nikkei Micro Device,” pp. 44-71, the April 1998 issue of “Nikkei Micro Device,” pp. 164-167, Pub. No. U.S. 2001/003049 A1, and Pub. No. U.S. 2002/030258 A1).

The wafer-level CSP is known in two kinds, the encapsulating resin type and the rewiring type. The encapsulating resin type adopts the structure which has the surface thereof covered with a sealing resin in the same manner as that of the conventional package, namely the structure which results from erecting a metal post on a wiring layer and solidifying the periphery thereof with a sealing resin. When a package is mounted on a printed board, the stress which is generated by the difference of thermal expansion from the printed board is concentrated in the metal post. It is known that the stress is dispersed by elongating the metal post.

The rewiring type has a rewiring formed without using a sealing resin as illustrated in FIG. 1. It results from laminating an Al electrode 2, a wiring layer 3, and an insulating layer 4 on the surface of a chip 1, forming a metal post 5 on the wiring layer 3, and forming a solder bump 6. The wiring layer 3 is used as a rewiring for disposing the solder ball on the chip 1.

The sealing resin type enjoys high reliability but necessitates a complicated process. The rewiring type enjoys a simple process and is at an advantage in allowing nearly all steps to be implemented by the wafer process. It is, however, required to relax the stress to be generated and exalt the reliability by procuring materials and structures and combinations thereof which have not existed hitherto.

As a photopolymerizing laminated piece formed of a specific resin composition, the laminate using a resinous component possessing a fluorene skeleton is known (refer to WO00/58788). This publication has a statement that the photopolymerizing film material illustrated therein excels in resolution. Though the invention of this publication suggests applicability to semiconductor devices, it is mainly aimed at application to a wiring board for mounting a semiconductor device and is not proposed for application to a semiconductor device of a specific structure.

### BRIEF SUMMARY OF THE INVENTION

FIG. 2 is a cross section which depicts the case of mounting a chip size package 8 on a printed board 11. The solder ball 6 is electrically connected by being contact bonded to a copper electrode 10 laid on the printed board 11. Owing to the difference in thermal expansion between the printed board 11 and the chip-size package 8, however, a large shear stress occurs in the interface between the solder ball 6 and a metal post 5 and inflicts a fracture to the solder ball 6.

This invention is aimed at providing a wafer-level package which is enabled to relax the stress occurring in a chip-size package and exalt the reliability thereof to be manifested when it is mounted on a printed board and a method for the production hereof.

The invention disclosed herein will be outlined below.

The wafer-level package according to the first aspect of this invention is a wafer-level package of a semiconductor substrate which possesses either or both of an electrode part and a wiring layer connected to an electrode part. It is characterized by forming an insulating layer formed mainly of a fluorene skeleton-containing resin on the semiconductor substrate, one step or a plurality of steps of posts on the electrode part, and bumps formed of electroconductive balls on the posts.

According to this configuration, it is made possible to select the material of the posts and the material of the electroconductive balls in conformity with the structures and the materials of the other component members and as well adopt the structures and the materials which are proper for relaxing the shear stress. The insulating layer formed mainly of the fluorene skeleton-containing resin may be either a thermosetting product or a photosensitive product. The patterning operation involved herein resorts to the process of photolithography when the insulating layer uses a photosensitive resin. The patterning with a laser is available when the insulating layer uses a thermosetting resin. The material of the posts may be any of metal, alloy, and electroconductive polymer so long as it is endowed with electroconductivity. The posts may be formed of a combination of the materials enumerated above. The material may be properly selected to suit the purpose of use. The number of steps of posts may be designed to suit the occasion. The electroconductive balls may use a metal or a heat-resistant polymer for the core part thereof and a solder component for the peripheral part thereof, for example. Copper is frequently used as the core metal. The solder balls may be formed of a component properly selected to suit the purpose of use.

The wafer-level package according to the second aspect of this invention is characterized by giving a height in the range of 5-200 μm to the posts used in the configuration of the first aspect of the invention. If the height of the posts falls short of 5 μm, the shortage will possibly result in preventing the effect of relaxing the stress from being fulfilled as expected. Conversely, if the height exceeds 200 μm, the excess will possibly result in aggravating the influence of the difference of thermal expansion between the posts and the resin enclosing them and exerting a large stress on the posts. Since the time required for manufacturing the posts by plating or sputtering must be taken into consideration in spite of the restriction on the combination with other component parts, the height falls more preferably in the range of 30-150 μm.

The wafer-level package according to the third aspect of this invention is characterized by giving a major axis in the range of 5-200 μm to the posts used in the configuration of the first aspect of the invention mentioned above. If the major axis of the posts falls short of 5 μm, the shortage will possibly result in rendering the adhesion of the posts to the electroconductive ball difficult in the present state of affairs in consideration of the accuracy with which the component members will be aligned during the subsequent step of packaging. If this major axis exceeds 200 μm, the excess will result in adding to the possibility of preventing the existing chip size from being decreased. The major axis of the posts corresponds to the diameter when the posts have a circular cross section and to the longest lengths in the relevant diameters and diagonal lines when the posts have elliptic, angular, and hexagonal cross sections. From the viewpoint of relaxing the concentration of stress, the posts are preferred to have a form of rotational symmetry. It is the form of a circular section that allows the most stable relaxation of stress.

The wafer-level package according to the fourth aspect of this invention is characterized by giving an aspect ratio of the height to the major axis (height/major axis) in the range of 0.03-10 to the posts used in the configuration of the first aspect of this invention. If the aspect ratio falls short of 0.03, the shortage will possibly result in preventing the effect of relaxing stress from being manifested as expected. If the aspect ratio exceeds 10, the excess will possibly result in suffering the difference of thermal expansion between the posts and the resin part to manifest its effect and further suffering generation of stress as well. The aspect ratio preferably falls in the range of 0.2-3, depending on the material used for the posts.

The wafer-level package according to the fifth aspect of this invention is characterized by the posts used in the configurations of the first through four aspects of the invention being formed of either or both of a metal and an alloy. The term “metal” used here in applies to all the metals appearing in the Periodic Table of the Elements and the term “alloy” used herein applies to all the alloys resulting from combining these metals. Those metals or alloys which are denatured on account of the conditions for manufacturing the posts and in consequence of the attachment of the posts to the solder balls are excluded. When the posts are formed on a plurality of steps, it is permissible to pile posts of one metal or alloy, posts of different metals, posts of different alloys, further posts of a metal and an alloy, and posts of a plurality of metals and a plurality of alloys.

The wafer-level package according to the sixth aspect of this invention is characterized by the posts in the configuration of the fifth aspect of this invention being formed of one member or two or more members selected from the group consisting of Ni, Ni—P type alloys, Ni—B type alloys, Ni—P—B type alloys, Fe—Ni type alloys, Cu, and Cu alloys. By combining the metals and the alloys mentioned above in an arbitrary combination to obtain the constituent of the posts, it is enabled to select the material possessing electric conductance and thermal expansion coefficient proper for a package. The expression “two or more members” as used herein implies a plurality of steps of posts. It applies, for example, to the case of having Cu set next to a Ni—P alloy.

The wafer-level package according to the seventh aspect of this invention is characterized by the fact that the fluorene skeleton-containing resin used in the configuration of the first aspect of this invention is a resin obtained by causing a fluorene epoxy(meth)acrylate represented by the following formula (1) to react with a polyvalent carboxylic acid or an anhydride thereof. 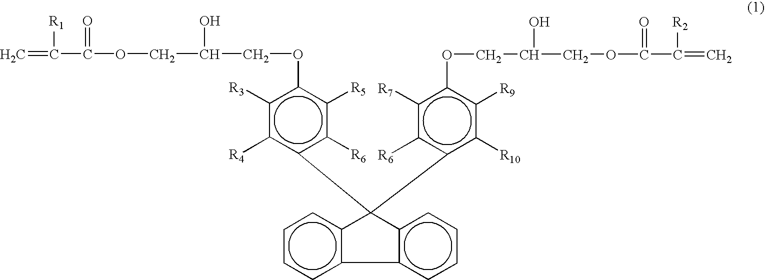
(wherein R₁ and R₂ are hydrogen or methyl group and different or identical with each other and R₃-R₁₀ are hydrogen, an alkyl group with 1-5 carbon atoms or halogen and different from or identical with one another).

The compounds of this formula occur in a multiplicity of kinds and these compounds are used in proper combinations. The resin which originates from the formula (1) possesses excellent resistance to heat and befits wafer-level packaging.

The wafer-level package according to the eighth aspect of this invention is characterized by the fact that the electroconductive balls used in the configuration of the first aspect of this invention are either or both of metallic balls and composite balls. The term “metallic balls” refers to balls of all the available metals in the Periodic Table of the Elements represented by copper, nickel, and iron and the alloys thereof and balls using such metals and alloys for the cores thereof and attaching a solder component to the peripheries thereof. The term “composite balls” refers to balls using a resin for the cores thereof and attaching a solder component to the peripheries thereof.

The wafer-level package according to the ninth aspect of this invention is characterized by the fact that the metallic balls used in the configuration of the eighth aspect of this invention are solder balls. As the component for the solder balls, all the publicly known components of the lead type and non-lead type of varying kinds are available.

The semiconductor device according to the 10^{th} aspect of this invention is characterized by being obtained from a wafer-level package set forth in any of the first through ninth aspects of this invention. This semiconductor device is possessed of a wafer-level package which is characterized by comprising a patterned insulating layer formed mainly of a fluorene skeleton-containing resin, one step or a plurality of steps of posts disposed on an electrode part, and a bump formed of an electroconductive ball on the posts. By possessing the wafer-level package according to this invention, the semiconductor device is enabled to be miniaturized to a greater extent than ever.

The electronic device according to the 11^{th} aspect of this invention is characterized by possessing a semiconductor device according to the 10^{th} aspect of this invention. By utilizing the 10^{th} aspect of this invention, the electronic device is enabled to fit miniaturization.

The method for the production of a wafer-level package according to the 12^{th} aspect of this invention is a method for producing a wafer-level package of a semiconductor substrate furnished with either or both of an electrode part and a wiring layer connected to an electrode part and is characterized by contact bonding a dry sheet or dry film formed mainly of a fluorene skeleton-containing resin on the semiconductor substrate by either or both of the application of heat under a vacuum or the use of a roller or applying thereto a liquid dielectric film and drying the applied film, subjecting the stated positions of either or both of the electrode part or the wiring layer to exposure and development of the photolithographic method thereby forming through holes in the dry sheet or dry film, subsequently forming one step or a plurality of steps of posts in the through holes, and joining electroconductive balls on the posts thereby forming bumps. The fluorene skeleton-containing resin possesses the nature of abounding in resistance to heat and can be manufactured into a dry sheet or dry film. The dry sheet or dry film having a thickness of 35, 50, and 70 μm is easily obtained. It may be produced in any other arbitrary thickness in the range of 5-200 μm. Since this resin is a photosensitive substance, patterning can be carried out by a photolithographic process. The fluorene skeleton-containing resin is preferred to be a resin which is obtained by causing a fluorene epoxy(meth)acrylate possessing the structure of the general formula (1) mentioned above to react with a polyvalent carboxylic acid or an anhydride thereof.

The method for producing a wafer-level package according to the 13^{th} aspect of this invention is characterized by using a reduced pressure of not more than 400 Pa during the contact bonding of the dry sheet or dry film in the method of the 12^{th} aspect of this invention. If the atmospheric pressure exceeds the specified reduced pressure, the excess will possibly result in impairing the tight adhesion during the contact bonding, suffering the dry sheet or dry film to peel during the course of the packaging step, and inducing inconveniences in the subsequent step.

The method for producing a wafer-level package according to the 14^{th} aspect of this invention is characterized by the fact that the method for the formation of the posts in the method of the 12^{th} aspect of the invention is one kind or two or more kinds selected from the group consisting of electroless plating, electroplating, and sputtering methods. The method for forming the posts has the degree of difficulty vary with the kind of metal or alloy. The method for forming the posts, therefore, must be selected in due consideration of this difficulty. Commendably, the cost is also taken into consideration in this selection.

The method for producing a wafer-level package according to the 15^{th} aspect of this invention is characterized by the fact that the method for forming the bumps in the method of the 12^{th} aspect of this invention consists in wholly or partly mounting balls on the wafer level. The relevant technology is advancing toward lowering the cost. The collective mounting of the balls on the wafer level promises a reduction in cost.

The method for producing a wafer-level package according the 16^{th} aspect of this invention is characterized by the fact that the method for forming the bump in the method of the 12^{th} aspect of this invention comprises mounting the balls on the wafer level and subsequently subjecting the balls to reflowing. By this method, it is made possible to join the mounted balls infallibly to the posts and consequently form bumps of high reliability.

The method for producing a wafer-level package according to the 17^{th} aspect of this invention is characterized by the fact that the method for forming bumps comprises wholly or partly mounting the balls on the wafer level and subsequently objecting the balls to reflowing. This process is the bump forming method that enables the balls to be joined infallibly at the lowest possible cost.

This invention brings the following effects.

(1) Owing to the erection of the posts by the use of the fluorene skeleton-containing resin, the stress in the interface for joining the posts and the chip is relaxed and the resistance to the thermal stress is exalted.

(2) The metal posts can be erected by properly using the electroless plating, electroplating, and sputtering methods. Consequently, various materials are made usable for the metal posts. The materials which are usable for the metal posts are Ni, Ni—P type alloy, Ni—B type alloy, Ni—P—B type alloy, Fe—Ni type alloy, Cu, and Cu type alloy. The metal posts formed of two or more kinds of materials are usable herein.

(3) The use of the fluorene skeleton-containing photosensitive resin obviates the necessity for using a sealing resin for an under fill and permits a further reduction in cost. The dry film can be formed with the resin of a thickness in the range of 5-200 μm.

### BRIEF DESCRIPTION OF THE DRAWINGS

FIG. 1 depicts a rewiring type wafer-level CSP.

FIG. 2 is a cross section illustrating the state in which a chip-size package and a printed board are joined.

FIG. 3 is a cross section illustrating the state in which an insulating layer is imparted to a wafer-size package of this invention.

FIG. 4 is a cross section illustrating the state in which a through hole is imparted to an insulating layer in the configuration of this invention.

FIG. 5 is a cross section illustrating the state in which a post of the first step is imparted to the configuration of this invention.

FIG. 6 is a cross section illustrating the state in which a post of the second step is imparted to the configuration of this invention.

FIG. 7 is a cross section illustrating the state in which a bump is formed in the configuration of this invention.

FIG. 8 is a diagram of a test chip.

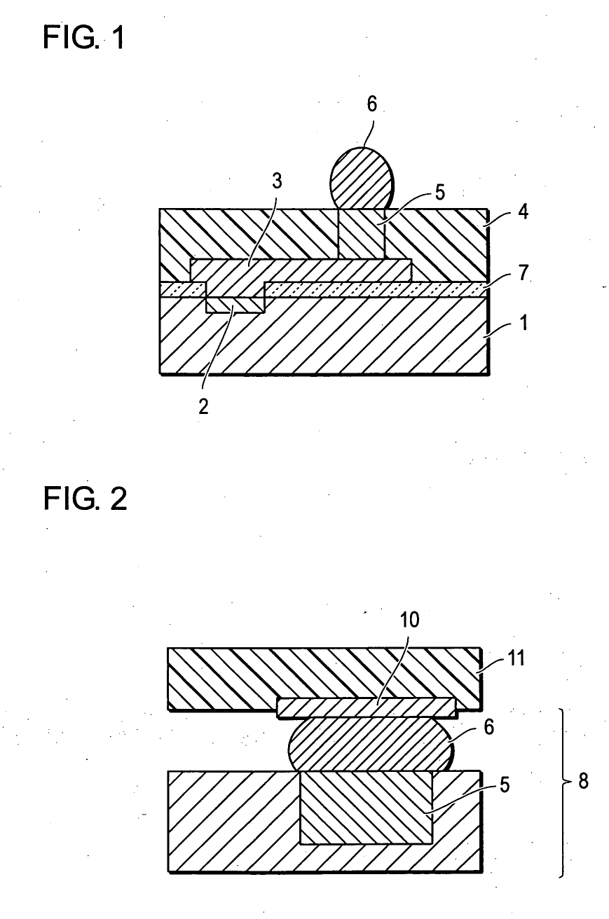

### DETAILED DESCRIPTION OF THE INVENTION

Now, the mode of embodiment of this invention will be described below with reference to the accompanying drawings.

The wafer-level package according to this invention will be explained below with the diagram of a chip level.

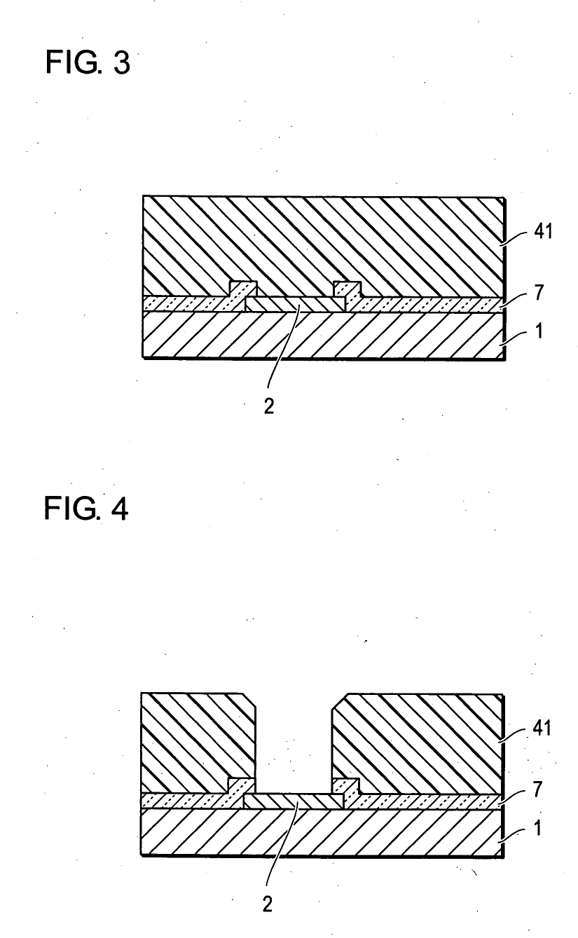

First, on a chip 1 having an electrode 2, a wiring layer, and a passivation layer 7 formed at stated positions, a dry sheet or dry film 41 formed mainly of a fluorene skeleton-containing resin is mounted as an insulating layer as illustrated in FIG. 3. The relevant heating is performed at a temperature falling in the range of 60-110° C. and particularly preferably in the range of 80-90° C. In this case, by performing the application under a reduced pressure of not more than 400 Pa, the adhesion of the wafer forming a chip and the dry sheet or dry film is attained with thorough fastness. When the resin obtained by causing a fluorene epoxy (meth)acrylate having the structure of the aforementioned general formula (1) to react with a polyvalent carboxylic acid or an anhydride thereof is used as the fluorene skeleton-containing resin, since this resin excels in the property to follow the contour of the surface of a wafer chip, the fast adhesion can be obtained infallibly without giving rise to voids in the interface between the wafer and the insulating layer. The dry film (sheet) formed mainly of the fluorene skeleton-containing resin is produced by preparing a mixed solution having 50-70 parts by weight, preferably 60 parts by weight, of a resin obtained by causing a fluorene epoxyacrylate represented by the aforementioned general formula (1) (wherein all of R₁-R₁₀ are hydrogen atoms) to react with a mixture of tetrahydrophthalic anhydride and benzophenone tetracaraboxylic acid dianhydride (0.5:0.5), 10-20 parts by weight, preferably 15 parts by weight, of trimethylol propane triacrylate as another unsaturated compound, 5-10 parts by weight, preferably 7 parts by weight, of a cross-linked rubber having an average particle diameter of 0.07 μm and serving as a cross-linked elastic polymer, 5-20 parts by weight, preferably 15 parts by weight, of a bisphenol type epoxy resin, and 1-5 parts by weight, preferably 3 parts by weight, of a photopolymerization initiator, a sensitizer, and other additives dispersed in a solvent, applying the mixed solution with a die coater in a prescribed thickness on a polyester film, and drying the resultant applied layer in a continuous four-step drying oven set in advance at a temperature in the range of 80-120° C. The pasting of the dry sheet to the substrate may be accomplished by feeding the dry sheet together with the wafer into the roller little by little from the one side forward so as to avoid inclusion of bubbles between the adjoining component layers. The thickness of the insulating layer preferably falls in the range of 5-200 μm. If this thickness falls short of 5 μm, the shortage will possibly result in impeding impartation of sufficient insulation and preventing the posts to be formed at a subsequent step from manifesting an effect of relaxing stress, depending on the contour of the surface of the wafer. If the thickness exceeds 200 μm, the excess will be at a disadvantage in rendering the dry sheet or dry film unduly expensive and the posts liable to induce concentration of stress. When the liquid dielectric film is used, the application of the mixed solution thereto is effected by the same method as the photoresist by the use of a spin coater and the applied layer is dried at a temperature in the range of 80-150° C. As the material of the liquid dielectric film, the aforementioned fluorene skeleton-containing resin or a commercially available equivalent may be used.

Next, on the prescribed electrode 2 on the chip 1, a through hole reaching the electrode 2 is formed in the aforementioned insulating layer as illustrated in FIG. 4. Though the form of the resultant through hole does not need to be particularly restricted, it may be any of various forms such as circle, ellipsis, square, and octagon. From the viewpoint of relaxing the concentration of stress on the posts, the through hole assumes preferably a form of rotational symmetry and most preferably a circular form. Further, the through hole is preferred to have a major axis in the range of 5-200 μm. The term “major axis” as used herein corresponds to the diameter when the through hole has a circular form. When the through hole has an elliptic form, a square form, or an octagonal form, the term corresponds to the largest lengths in the relevant diameters and diagonal lines. If the major axis of the through hole falls short of 5 μm, the shortage will possibly result in rendering the adhesion of the posts to the electroconductive ball difficult in the present state of affairs in consideration of the accuracy with which the component members will be aligned during the subsequent step of packaging. If this major axis exceeds 200 μm, the excess will result in adding to the possibility of preventing the existing chip size from being decreased. When the aspect ratio of the depth to the major axis of the through hole (depth/major axis), namely the aspect ratio of the height to the major axis of the post to be formed at a subsequent step (height/major axis), is in the range of 0.03-10, it proves optimal in manifesting a large effect of relaxing the concentration of stress in the post.

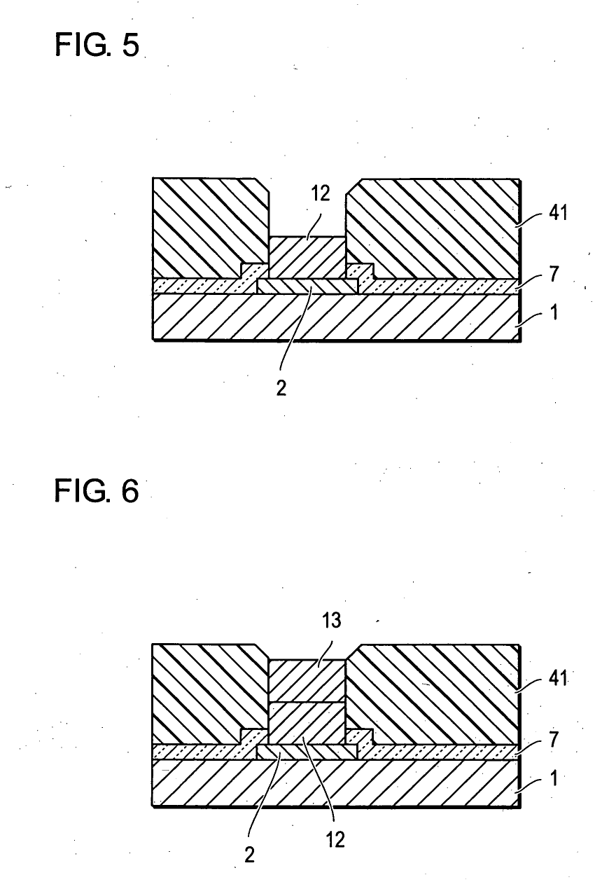

Further, posts 12, 13 are formed inone step or a plurality of steps as illustrated in FIG. 5 and FIG. 6 on the electrode 2 which has the through hole formed therein. The posts thus formed are preferred to be made of either or both of a metal and an alloy. They are preferably made of a metal and/or an alloy possessing good electroconductivity because electric connection must be secured between the electrode and the electroconductive ball on the chip. Particularly preferably, they are formed of one member or two or more members selected from the group consisting of Ni, Ni—P type alloy, Ni—B type alloy, Ni—P—B type alloy, Fe—Ni type alloy, Cu, and Cu alloy. The method for forming the posts is preferably one or two or more methods selected from among electroless plating, electroplating, and sputtering methods. The difficulty with which the posts are formed varies with the kind of metal or alloy. Since the methods enumerated above are capable of forming the posts comparatively easily, the method for forming the posts may be selected in consideration of the matter of cost.

Finally, the package contemplated by this invention is completed by mounting electroconductive balls 14 one each on the posts and joining the posts and the electroconductive balls. The material for the electroconductive balls does not need to be particularly restricted but is only required to possess electroconductivity. It may be any of metals, alloys, and electroconductive polymers. The electroconductive balls made of a metal (an alloy) prove particularly favorable because they can be easily joined to the metallic posts mentioned above. The balls made of all the available metals in the Periodic Table of the Elements represented by copper, nickel, and iron and the alloys thereof and the balls using such metals and alloys for the cores thereof and attaching a solder component to the peripheries thereof can be used as the metallic balls. When the solder balls are used as the metallic balls, they prove most favorable because they dissolve at a comparatively low temperature and form bumps infallibly. Since various compositions of the lead type or non-lead type are available as the material for the solder, the material may be properly selected to suit the purpose of use. As regards the composite balls, the resin destined to form the cores thereof may be an electroconductive substance or an insulative substance. The solder component on the surface serves to establish necessary continuity. Various compositions of the lead type or the non-lead type are available as the material for the solder. Thus, the material may be properly selected from such compositions to suit the purpose of use.

The method for forming the bump may comprise wholly or partly mounting electroconductive balls on the wafer level, mounting electroconductive balls on the wafer level, or wholly or partly mounting electroconductive balls on the wafer level and subsequently subjecting the balls to reflowing. Particularly, the method including wholly or partly mounting electroconductive balls on the wafer level and subsequently subjecting the balls to reflowing is the bump forming method that enables the balls to be joined infallibly at the lowest possible cost.

The semiconductor device of a smaller size than the conventional package can be obtained by dicing the wafer-level package manufactured as described above, separating the resultant dice into individual semiconductor packages, and mounting the semiconductor packages one each on printed boards. The miniaturization of an electronic device can be easily realized by the incorporation of this semiconductor device.

### EXAMPLES

### Example 1

A wafer-level package was manufactured by following the steps illustrated in FIGS. 3-7.

First, a dry film 5 μm in thickness or a dry sheet 35 μm in thickness, each formed mainly of a fluorene skeleton-containing resin, was pasted on a 4-inch (100 mm) wafer forming therein 61 chips each furnished with 276 Al electrodes and a passivation layer in an atmosphere of a reduced pressure of 400±40 Pa at 80° C. as shown in FIG. 3. Here, the dry film (sheet) formed mainly of the aforementioned fluorene skeleton-containing resin was produced by preparing a mixed solution having 60 parts by weight of a resin obtained by causing a fluorene epoxyacrylate represented by the aforementioned general formula (1) (wherein all of R₁-R₁₀ are hydrogen atoms) to react with a mixture of tetrahydrophthalic anhydride and benzophenone tetracaraboxylic acid dianhydride (0.5:0.5), 15 parts by weight of trimethylol propane triacrylate as another unsaturated compound, 7 parts by weight of a cross-linked rubber having an average particle diameter of 0.07 μm and serving as a cross-linked elastic polymer, 15 parts by weight of a bisphenol type epoxy resin, and 3 parts by weight of a photopolymerization initiator, a sensitizer, and other additives dispersed in a solvent, applying the mixed solution with a die coater in a prescribed thickness on a polyester film, and drying the resultant applied layer in a continuous four-step drying oven set in advance at a temperature in the range of 80-120° C.

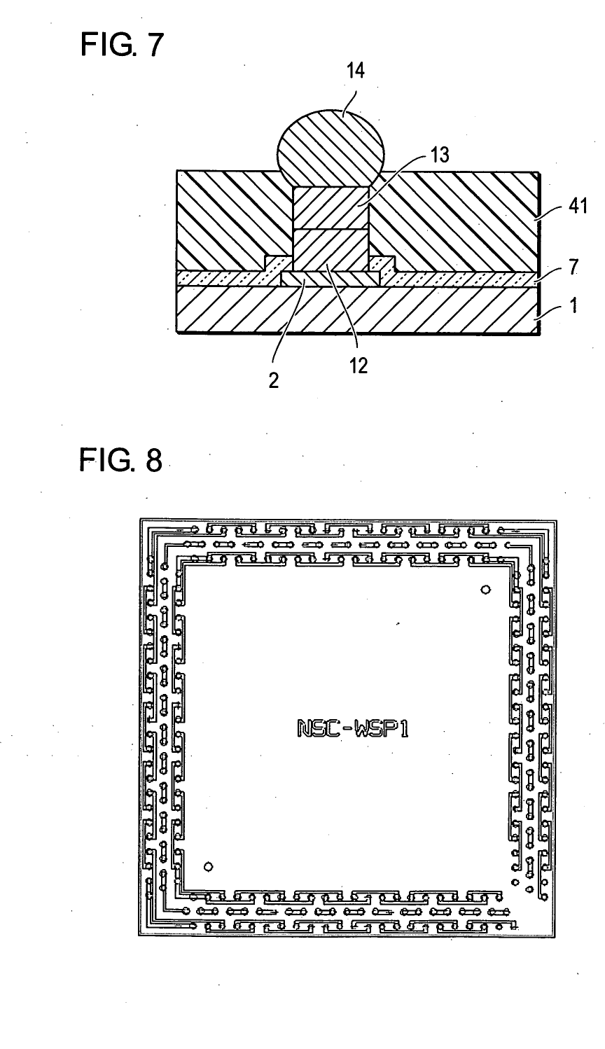

Next, circular through holes 130 μm in diameter were formed in portions corresponding to the individual electrodes formed at prescribed positions of a wafer by the photolithographic method as shown in FIG. 4. Subsequently, posts were formed inside the through holes on the Al electrode as illustrated in FIG. 5 and FIG. 6. In each wafer, posts of a nickel-phosphorus alloy (Ni-11% P) ware formed in a thickness of 5 μm (aspect ratio 0.04) by the method of electroless plating on the Al electrodes. In the wafer coated with a sheet of resin 35 μm in thickness, copper was further deposited in a thickness of 30 μm (aspect ratio 0.23) by the method of electroless plating on the post of Ni-11% P to give rise to two-step posts (aspect ratio 0.27). Then, eutectic Sn—Pb solder balls 150 μm in diameter were mounted one each on the formed posts and subsequently subjected to reflowing at 230° C. to give rise to bumps, thereby producing the wafer-level package as illustrated in FIG. 7. The diagram of one of the test chips is shown in FIG. 8. The chips were squares, 10 mm×10 mm.

Thereafter, the wafer-level package consequently manufactured was diced into chip-size packages. The chip-size packages were joined to a printed board furnished with electrodes corresponding in position to the bumps and the packages were subjected to a temperature cycle test as follows.

The temperature cycle test was affected by carrying out a temperature change of −55° C. to 125° C. up to 1000 cycles (the speed of lowering temperature and the speed of elevating temperature were each set at 10° C./min.). Thereafter, the bumps on the chip-size packages were tested for continuity. When all the bumps on a given sample were confirmed to retain necessary continuity, this sample was found as acceptable.

When ten samples collected from an arbitrary position of a given wafer were subjected to the continuity test, the number of successful samples was five when the height of posts was 5 μm and nine when the height was 35 μm. The number of bumps of bad continuity was five and one respectively. The results of high reliability were obtained in samples having higher posts. When the test was performed by following the procedure described above while changing the height of posts to 50 μm (aspect ratio 0.38) and 70 μm (aspect ratio 0.54), all the ten samples used in each test passed the test. When the height of posts was changed to 200 μm (aspect ratio 1.54), nine out of ten samples passed the test. In the samples which passed the test, the circuits formed in the chips were found to be operating normally.

### Comparative Example

A dry film (sheet) was prepared by repeating the procedure of Example 1 while using a common bis-phenol A type epoxy acrylate possessing no fluorene skeleton in the place of the fluorene epoxy acrylate. A wafer-level package was manufactured by following the procedure of Example 1 while using a dry film 5 μm in thickness or a dry sheet 50 μm in thickness, each formed of the resultant resin possessing no fluorene skeleton. Ten chips collected from arbitrary positions were joined to a printed board and subjected to a temperature cycle test by following the procedure of Example 1.

When ten samples collected from arbitrary position of the wafer were subjected to the continuity test, the number of successful samples was two when the height of posts was 5 μm and five when the height was 50 μm. The results indicated poor reliability because the resin was deficient in resistance to heat.

Incidentally, the resin used in the comparative example was incapable of forming a sheet having a thickness exceeding 50 μm. Further, the film (sheet) obtained at all was deficient in resolution and was unable either to induce proper resolution in the portion having a high aspect ratio or to allow formation of copper posts. Besides, when the film (sheet) was pasted to the wafer in an atmosphere of a reduced pressure, it engulfed bubbles, oozed from the edge part, and failed to form a perfect insulating layer.

### Example 2

A wafer-level package was manufactured by following the procedure of Example 1 while changing the material of the posts directly on the electrode to a nickel-phosphorus alloy (Ni-7% P) and the major axis of the posts to 180 μm and was subjected to a temperature cycle test. As a result, five out of ten samples on the posts having a height of 5 μm (aspect ratio 0.03) and nine out of ten samples on the posts having a height of 35 μm (aspect ratio 0.19). It was consequently found that a change in the phosphorus content ratio in the posts brought no change in reliability. The results were the same as those of Example 1 when the height of the posts was in the range of 50-200 μm (aspect ratios 0.28-1.11).

### Example 3

A wafer-level package was manufactured by following the procedure of Example 1 while changing the material of the posts directly on the electrodes to a nickel-phosphorus alloy (Ni-7% P), the major axis to 180 μm, the electroconductive balls to the core-shell type two-layer structure, and using metallic balls 230 μm in diameter each comprising a core part of copper 80 μm in diameter and a shell part of a Sn—Pb type eutectic solder component 75 μm in thickness and was subjected to a temperature cycle test. As a result, nine out of ten samples on the posts 35 μm in height (aspect ratio 0.19) passed the test. It was found that the reliability was not affected by a change in the phosphorus content ratio of the posts and a change in the material for the metallic balls. The results were the same as those of Example 1 when the height of the posts was in the range of 50-200 μm.

### Example 4

A wafer-level package was manufactured by following the procedure of Example 1 while changing the material of the posts directly on the electrodes to Ni-1% B, Ni-2% P-0.1% B, Fe-3% Ni, Cu, or Cu-3% Sn alloy and was subjected to a temperature cycle test. As a result, five out of ten samples on the posts 5 μm in height and nine out of ten samples on the posts 35 μm passed the test. It was found that a change in the phosphorus content ratio in the posts brought no change in the reliability. The results were the same as those of Example 1 when the height of posts was in the range of 50-200 μm.

### Example 5

A post component was manufactured by following the procedure of Example 1 while using the electroplating method instead. The posts had a major axis of 180 μm. Posts of nickel were formed in a thickness of 5 μm (aspect ratio 0.03) on Al electrodes. In a wafer covered with a sheet of resin 35 μm in thickness, copper was further deposited on the posts of Ni by the method of electroplating to give rise to two-step posts (aspect ratio 0.19). Ten chips were collected from arbitrary positions and joined to a printed board in the same manner as in Example 1 and then subjected to a temperature cycle test. As a result, the number of successful samples was five when the height of the post was 5 μm and nine when the height was 35 μm. The number of samples suffering from inferior continuity was five and one respectively. The results of high reliability were obtained when the posts had a greater height. All the ten samples having post heights of 50 μm (aspect ratio 0.28) and 70 μm (aspect ratio 0.38) passed the test. Nine out of ten samples having a post height of 200 μm (aspect ratio 1.11) passed the test.

### Example 6

A wafer-level package was manufactured by following the procedure of Example 1 while placing a sheet on a wafer and joining the sheet fast thereto with a roller operated from one end thereof forward under a pressure of 600 Pa instead of contact bonding the sheet by application of heat under a reduced pressure. When it was evaluated, it yielded the same results.

### Example 7

A film was formed by following the procedure of Example 1 while avoiding use of a dry film (sheet) formed mainly of a fluorene skeleton-containing resin, not causing the residual solvent to be dried in the final stage of the manufacture of the sheet, preparing a resin-containing solution with necessary viscosity, applying the solution with a spin coater, and drying the applied layer of the solution. Posts were formed in the same manner as in Example 1 and subjected to a temperature cycle test. The results were the same as those of Example 1.

1. A wafer-level package of a semiconductor substrate possessed of either or both of an electrode part and a wiring layer connected to an electrode part, which is provided on said semiconductor substrate with an insulating layer formed mainly of a fluorene skeleton-containing resin and on said electrode part with one step or a plurality of steps of posts, and on said posts with bumps formed of electroconductive balls.

2. A wafer-level package according to claim 1, wherein said posts have a height in the range of 5-200 μm.

3. A wafer-level package according to claim 1, wherein said posts have a major axis in the range of 5-200 μm.

4. A wafer-level package according to claim 1, wherein the aspect ratio of the height to the major axis of said posts (height/major axis) is in the range of 0.03-10.

5. A wafer-level package according to claim 1, wherein said posts are made of either or both of a metal and an alloy.

6. A wafer-level package according to claim 5, wherein the material of said posts is one member or two or more members selected from the group consisting of Ni, Ni—P type alloy, Ni—B type alloy, Ni—P—B type alloy, Fe—Ni type alloy, Cu, and Cu alloy.

7. A wafer-level package according to claim 1, wherein said fluorene skeleton-containing resin is a resin obtained by causing a fluorene epoxy(meth)acrylate represented by the general formula (1) to react with a polyvalent carboxylic acid or an anhydride thereof. 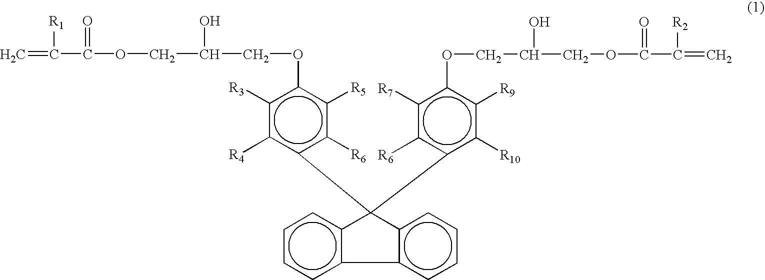
(wherein R₁ and R₂ are hydrogen or methyl group and different or identical with each other and R₃-R₁₀ are hydrogen, an alkyl group with 1-5 carbon atoms or halogen and different from or identical with one another).

8. A wafer-level package according to claim 1, wherein said electroconductive balls are either or both of metallic balls and composite balls.

9. A wafer-level package according to claim 8, wherein said metallic balls are solder balls.

10. A semiconductor device obtained from a wafer-level package set forth in claim 1.

11. An electronic device furnished with a semiconductor device set forth in claim 10.

12. A method for the production of a wafer-level package of a semiconductor substrate furnished with either or both of an electrode part and a wiring layer connected to an electrode part, which comprises contact bonding a dry sheet or dry film formed mainly of a fluorene skeleton-containing resin on the semiconductor substrate by either or both of the application of heat under a vacuum or the use of a roller or applying thereto a liquid dielectric film and drying the applied film, subjecting the stated positions of either or both of the electrode part or the wiring layer to exposure and development of the photolithographic method thereby forming through holes in the dry sheet or dry film, subsequently forming one step or a plurality of steps of posts in the through holes, and joining electroconductive balls on the posts thereby forming bumps.

13. A method for the production of a wafer-level package according to claim 12, wherein said reduced pressure is not higher than 400 Pa.

14. A method according to claim 12, wherein the method for forming said posts is one or two or more methods selected from the group consisting of the method of electroless plating, the method of electroplating, and the method of sputtering.

15. A method according to claim 12, wherein the method for forming said bumps consists in wholly or partly mounting the balls on the wafer level.

16. A method according to claim 12, wherein the method for forming said bumps comprises mounting the balls on the wafer level and subsequently subjecting the balls to reflowing.

17. A method according to claim 12, wherein the method for forming said bumps comprises wholly or partially mounting the balls on the wafer level and subjecting the balls to reflowing.
